(19) United States
(12) Patent Application Publication
(10) Pub. No.: US 2024/0260140 A1
(43) Pub. Date: Aug. 1, 2024

(54) Battery-Powered Heating Pads

(71) Applicant: XOTHRM LLC, Boise, ID (US)

(72) Inventors: JoHan Wang, Boise, ID (US); Sean T. Whalen, Mountain View, CA (US)

(21) Appl. No.: 18/425,937

(22) Filed: Jan. 29, 2024

Related U.S. Application Data
(60) Provisional application No. 63/441,831, filed on Jan. 29, 2023.

(51) Int. Cl. H05B 1/02; A47G 9/02; G01K 1/02; G01K 3/00; G05D 23/19; H05B 3/34; H05K 1/18

(52) U.S. Cl. CPC H05B 1/0272; A47G 9/0215; G01K 1/026; G01K 3/005; G05D 23/1931; H05K 1/18; H05B 3/342; H05K 2201/10022; H05K 2201/10037

(57) ABSTRACT

In one instance, a heating pad is disclosed that is flexible, battery-power, and weighted. The heating pad includes a sleeve formed with a top layer and a bottom layer and having an interior. A weighted segment layer is disposed within the interior of the sleeve. The weighted segment layer may include a plurality of pockets each having a plurality of weights. A conductive layer or sheet is disposed within the interior of the sleeve closer to the user than the weighted segment layer when in the deployed position. A battery and control unit is electrically coupled to the conductive layer for selectively providing power to the conductive layer. At least one temperature sensor is coupled to the conductive layer and electrically coupled to the control unit and provides safety features. Other heating pads are presented.

### CROSS-REFERENCE TO RELATED APPLICATION

This application claims the benefit of U.S. Provisional Application Ser. No. 63/441,831, filed on Jan. 29, 2023, entitled “Battery-Powered Heating Pad,” which is incorporated herein by reference in its entirety for all purposes.

### TECHNICAL FIELD

This application is directed, in general, to heating pads, and more specifically, to battery-powered heating pads.

### BACKGROUND

The following discussion of the background is intended to facilitate an understanding of the present disclosure only. It should be appreciated that the discussion is not an acknowledgement or admission that any of the material referred to was part of the common general knowledge at the priority date of the application.

After a person engages in exercise or other activity, it is desirable at times to take certain actions to expedite or facilitate recovery or comfort with respect to the person's muscles. Some products have been developed to provide pain relief, support and even treat injury, edema and muscle or joint pain for portions of the body. After exercise or in other situations such as when one has a sore muscle or body pains, a heating pad may be helpful. Heating pads have existed for a long time, and yet, improvements remain desirable.

### SUMMARY

According to an illustrative embodiment, a heating pad for application on a portion of a user's body includes a top layer having a first side and a second side, and a weighted-segment layer having a plurality of pockets and having a first side and a second side. The first side of the weighted-segment layer is below the second side of the top layer. The heating pad also includes a heating element having a conductive layer with a first side and second side. The first side of the conductive layer is below the second side of the weighted-segment layer, and the conductive layer creates heat when a current moves across the conductive layer. The heating pad further includes at least one thermistor associated with the conductive layer and a bottom layer having a first side and a second side. The first side of the bottom layer is below the second side of the conductive layer. The heating pad also has an end portion.

The end portion includes a battery housing coupled at least to the top layer or bottom layer or an electronics housing. The electronics housing is coupled at least to the top layer or bottom layer or the battery housing. The end portion also includes a battery cover coupled at least to the top layer or bottom layer or the battery housing, a printed circuit board associated, and at least one battery electrically coupled to the printed circuit board and to the heating element.

In another illustrative embodiment analogous to that of the preceding paragraphs, the heating pad further includes a plurality of seams formed at least by coupling a portion of the top layer and a portion of the weighted-segment layer. In still another embodiment, the heating element is configured to have a power flux between 0.5 and 1.5 watts per square inch.

According to another illustrative embodiment, a heating pad includes a sleeve formed with a top layer and a bottom layer. The sleeve has an interior. The bottom layer is against a user when in a deployed position. The heating pad further includes a weighted segment layer disposed within the interior of the sleeve. The weighted segment layer includes a plurality of pockets each having a plurality of weights therein. The heating pad also includes a conductive layer disposed within the interior of the sleeve closer to the user than the weighted segment layer when in the deployed position and includes a battery and control unit electrically coupled to the conductive layer for selectively providing power to the conductive layer. The sleeve, weighted segment layer, and conductive layer are flexible enough to articulate about portions of the user's body. At least one temperature sensor is coupled to the conductive layer and electrically coupled to the control unit. Other methods and heating pads are presented below.

### DESCRIPTION OF THE DRAWINGS

Illustrative embodiments of the present invention are described in detail below with reference to the attached drawing figures, which are incorporated by reference herein and wherein:

FIG. 1 is a schematic perspective view of an illustrative embodiment of a heating pad applied to a user's right leg;

FIG. 2 is a schematic top perspective view of an illustrative embodiment of a heating pad;

FIG. 3 is a schematic top plan view of an illustrative embodiment of a heating pad;

FIG. 4 is a schematic end view of an illustrative embodiment of a heating pad;

FIG. 5 is a schematic side elevation view of an illustrative embodiment of a heating pad;

FIG. 6 is a schematic cross-sectional view of the illustrative embodiment of a heating pad of FIG. 5 taken along line 6-6;

FIG. 6 is a schematic, partially exploded top perspective view of an illustrative embodiment of a heating pad;

FIG. 8 is a schematic, partially exploded side elevation view of an illustrative embodiment of a heating pad;

FIG. 9 is a schematic, partially exploded end view of an illustrative embodiment of a heating pad;

FIG. 10 is a schematic, perspective view of an illustrative embodiment of an electronics housing with a printed circuit board for use as an aspect of an illustrative embodiment of a heating pad;

FIG. 11 is a schematic cross-sectional view of an illustrative embodiment of a heating pad showing placement of heat sensors;

FIG. 12 is a schematic cross-sectional view of an illustrative embodiment of a heating pad shown on a user's shoulder;

FIG. 13 is a schematic, exploded perspective view of an illustrative embodiment of a heating element for use as an aspect of an illustrative embodiment of a heating pad;

FIG. 14 is a schematic, partially exploded side elevation view of an illustrative embodiment of the heating element of FIG. 13;

FIG. 15 is a schematic, bottom plan view of an illustrative embodiment of the heating element of FIG. 13;

FIG. 16 is a schematic perspective view of a portion of an illustrative embodiment of a battery cover for using as an aspect of an illustrative embodiment of a heating pad;

FIG. 17 is a schematic cross-sectional view of an illustrative embodiment of a portion of a battery cover with an illustrative embodiment of a battery disposed within the portion of the battery cover;

FIG. 18 is a schematic top pan view of an illustrative embodiment of a weighted segment layer as an aspect of an illustrative embodiment of a heating pad;

FIG. 19 is a detail of a portion of the weighted segment layer of FIG. 18 according to an illustrative embodiment; and

FIG. 20 is a detail of a portion of the weighted segment layer of FIG. 18 according to an illustrative embodiment.

### DETAILED DESCRIPTION

In the following detailed description of the preferred embodiments, reference is made to the accompanying drawings that form a part hereof, and in which is shown, by way of illustration, specific embodiments in which the invention may be practiced. These embodiments are described in sufficient detail to enable those skilled in the art to practice the invention, and it is understood that other embodiments may be utilized and that logical structural, mechanical, electrical, and chemical changes may be made without departing from the spirit or scope of the invention. To avoid detail not necessary to enable those skilled in the art to practice the invention, the description may omit certain information known to those skilled in the art. The following detailed description is, therefore, not to be taken in a limiting sense, and the scope of the present invention is defined only by the claims.

Unless otherwise indicated, as used throughout this document, “or” does not require mutual exclusivity.

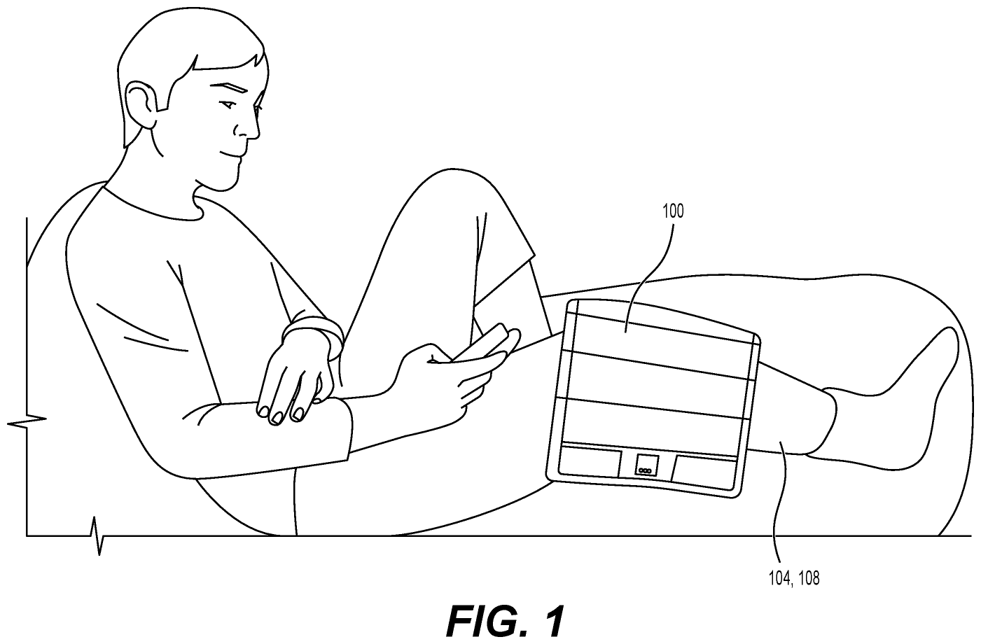

Referring now to the drawings and initially to FIG. 1, an improved heating pad 100 is shown on the right leg 104 of a user 108. While shown on a leg, it should be understood that the heating pad 100 may be used on a user's arms, back, shoulder, or any portion of the user 108. The heating pad 100 is self-contained and is battery operated.

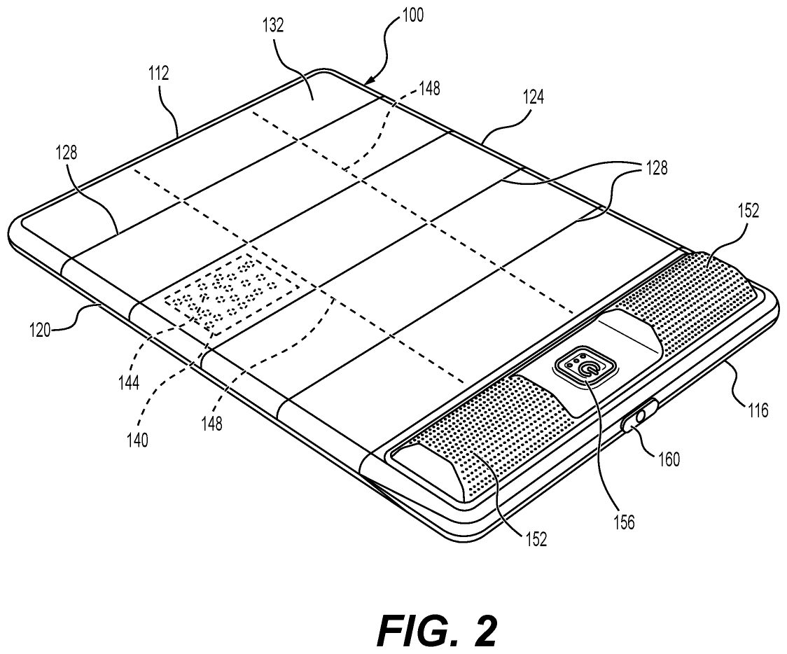

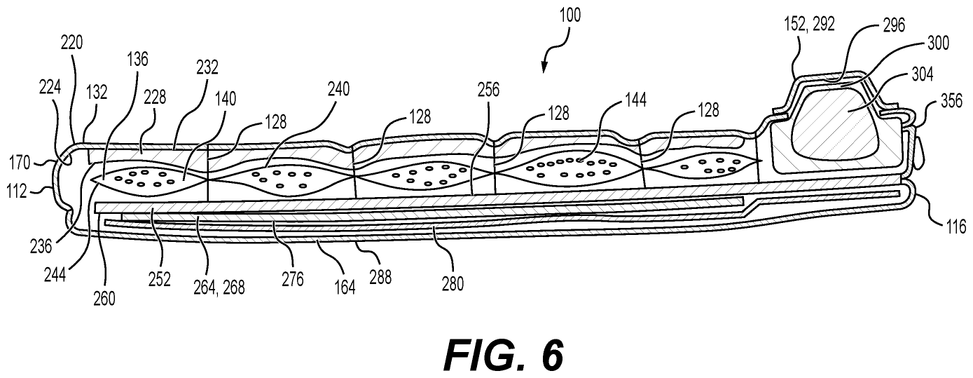

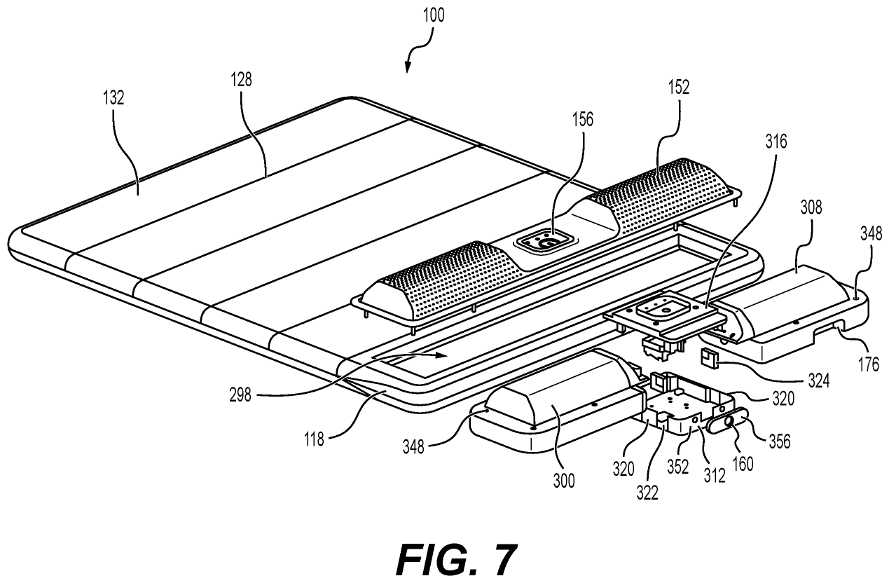

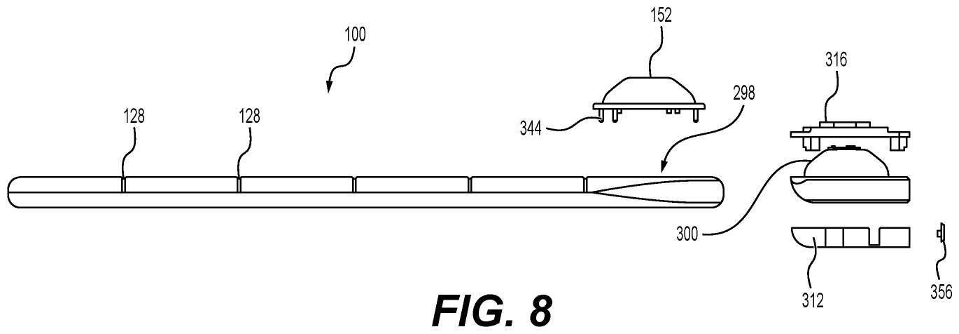

Referring now to FIGS. 2-8, an illustrative embodiment of the heating pad 100 will be presented in more detail. Referring initially to FIGS. 2-5, the heating pad 100 has a first lateral edge 112, a second lateral edge 116, a first longitudinal edge 120, and a second longitudinal edge 124. The heating pad is formed with a plurality of seams or hinge lines 128 that run laterally and facilitate wrapping of the heating pad 100 around or in conformity with a portion of a user's body. As used herein, “top” means furthest from the user's body when in an applied potion, and reference to above and below are with respect to the order of layers with the top layer being outermost from the user and bottom being closes to the user; in one illustrative embodiments going from top to bottom (see FIG. 6) the following layers would be encountered in some locations: top layer 132, compressible foam 228, weighted segment layer 136, insulating layer 252, heating element 264, bonding film 280, and bottom layer 164.

The plurality of seams 128, or hinges or pleats, are formed by stitching or partially coupling aspects of the heating pad, including at least a top layer 132, and a weighted-segment layer 136 (FIG. 6) that includes a plurality of pockets 140 (one shown in broken lines in FIG. 2) filled with BBs 144 or small weights, e.g., weighing less than 0.5 grams in some embodiments (broken lines in FIG. 2) or other weighted elements like metal bricks. Internal longitudinal weld lines or stitches 148 or seam (broken lines in FIG. 2) show that a grid of 3×5 pockets have been formed by the longitudinal weld or stitches 148 and lateral stiches or welds that coincide or substantially coincide with the seams 128. In some embodiments, the longitudinal weld or stiches 148 may be visible on an exterior. Other grid sizes and pocket patterns may be used and grid lines and seam lines do not need to line up. Weld or stitch lines 148 may be perpendicular or may be arranged in other patterns like diagonal, cross hatch, or hexagonal patterns to facilitate different bend or articulation joints.

The number of pockets 140 may vary with size, but a ratio between one pocket per 5 to 15 square inches is desired. In one embodiment, the ratio is 1 pocket 10 square inches; 15″×10″ with 15 pockets. Another approach to coordinating pocket 140 number is to have an articulation separation that is between 1.5 to 3 inches on the width (lateral) and 2 to 5 inches on the length (longitudinal). The more weld lines one has, the less weight of BBs one can capture. Considerable work has been involved in determining an acceptable ratio.

The top cover 132 and bottom cover 164 may be made from a fabric or a thin plastic. In some embodiments, the top layer or cover 132 and bottom layer or cover 164 may be made from polyurethane coated fabrics, PVC coated fabrics or a similar material, urethane molds, latex rubber, stretch loop, SPANDEX material, densely knit nylon fabric, or other materials. In some embodiments, the top cover 132 is thicker than the bottom layer 164. A thicker top layer 132 may be useful because a thicker top layer 132 helps direct the heat towards the user and facilitates flexibility or articulation of the heating pad 100 to accommodate portions of a user's body.

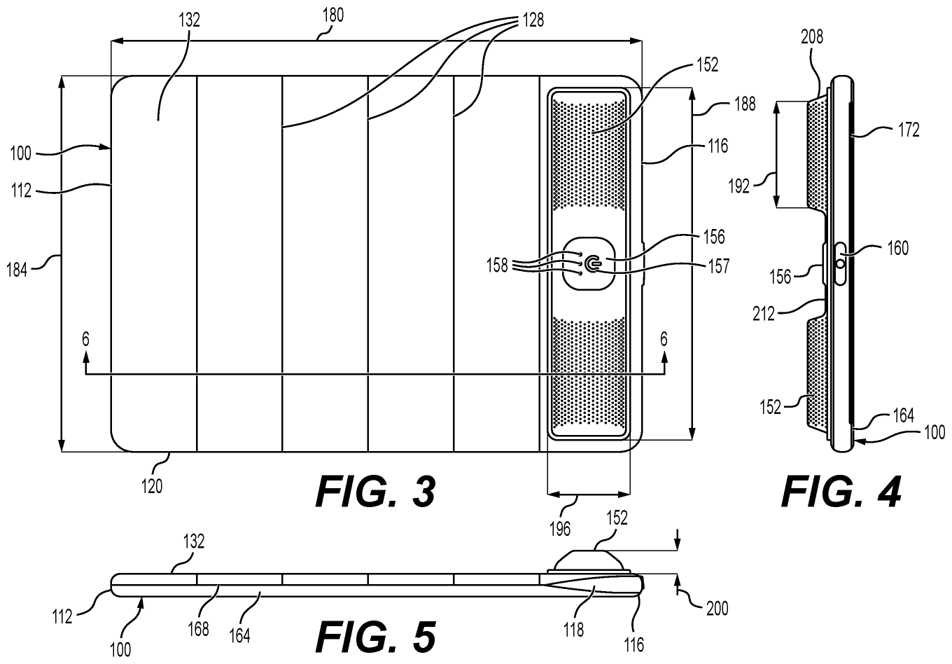

A battery cover or covering 152 is coupled to the top layer 132 proximate the second longitudinal end 116, or edge. The battery cover 152 also covers electronics and offers a control interface 156 with power or selection buttons 157 and LED or other displays 158 (FIG. 3). The displays 158 may indicate battery status, heating selection, timeout of heating session, errors detected, charging state, connected state if connected via a wireless connection to an auxiliary controller etc. A power port 160 for receiving a charging source is shown on the second longitudinal end 116, but could be placed at other locations. In FIG. 5, one may see where the top layer 132 is coupled to a bottom layer 164 at a peripheral edge to form a coupled peripheral edge 168. In some embodiments, the battery cover 152 may be just another portion of the top layer 132. In some embodiments, the battery cover 152 is formed from a flexible rubber or plastic or other material and may have varying thicknesses to facilitate bending at desired locations. In some embodiments the top and bottom cover or layer may be integrally formed, for example through a molding process and the peripheral edge 168 may similarly be integrally formed as part of that process.

In one illustrative embodiment, the control interface 156 is a single button that does all the necessary inputs. For example, with LEDS OFF:
quick press will show battery indication
long press will turn heater on to LOW setting, subsequent short presses will cycle though heat settings, at any point while it's heating a long press will turn it off and LEDs off
a Beep or vibration may accompany all button presses to assist when one cannot see the display (as when using on one's back)
at any point holding the button down for a very long press will reset the microcontroller
short press is <2s, long press is >2s and <7s, and very long press for the reset is 7s for reference.

The coupled peripheral edge 168 formed by coupling the top layer 132 and bottom layer 164 at peripheral ends forms a sleeve 170 (FIG. 5) that contains at least the weighted-segment layer 136 and a heating element 264. In some embodiments, the top layer 132 and bottom layer 164 are formed from a continuous sheet of material and the coupling is inherent to an integral piece. Proximate the second lateral end 116, wings or extra fabric portions 118 (FIG. 5) are positioned to help gain some height on the heating pad 100 because otherwise the two sheets want to be flat in some embodiments.

As shown clearly in FIG. 4, a zipper 172, such as an invisible zipper, may be used to couple a portion of the top layer 132 and the bottom layer 164 while still providing access to the inside or a portion of the sleeve 170 for assembly or battery replacement. A slider (not explicitly shown) of the zipper 172 may be stowed in a slider-retention pocket 176 (FIG. 7) to keep it from bulging. In other embodiments the zipper may be replaced with a zip lock fastener or strong magnets, hook and loop fastener or maybe simply glued shut.

Those skilled in the art will appreciate that the dimensions of the heating pad may vary according to application. In one illustrative embodiment, the dimensions were as follows: longitudinal dimension 180 was 394 mm; lateral dimension 184 was 278 mm; dimension 188 was 261 mm; dimension 192 was 79 mm; dimension 196 was 61 mm; and dimension 200 was 16 mm. These dimensions may be varied for bigger or smaller overall sizes. In the embodiment presented, as shown well in FIG. 4, the heating pad 100 may have a first battery projection 204 and a second battery projection 208 with a cutaway or valley 212 between. A control interface 156 is positioned in the valley 212.

Referring now primarily to FIG. 6, a cross-sectional view of the heating pad 100 is presented. The layers proximate the first longitudinal end 112 will first be presented going from top to bottom (for the orientation shown). There is the top layer 132, which has a first side 220 and a second side 224. The top layer 132 may be any suitable material, and in one embodiment is a PVC material. A first compressible foam layer 228 having a first side 232 and a second side 236 follows. The first side 232 of the first compressible foam layer 228 is below the second side 224 of the top layer 132, and the second side 236 of the first compressible foam layer 228 is above a first side 240 of the weighted-segment layer 136.

The weighted-segment layer 136 has a second side 244. The weighted-segment layer 136 has the plurality of pockets 140 formed by two pieces of material coupled by stitching or other means at or near or forming the seams 128 and longitudinal weld or stitching 148 (FIG. 2). The weighted-segment layer 136 may be a pair of polypropylene fabric layers stitched or heat sealed or welded or otherwise coupled to form the pockets 140 that hold small weights or BBs 144.

In one illustrative embodiment, the weighted-segment layer 136 is formed as follows. A first panel of sheet material (fabric or plastic sheet) is provided, and a second panel of sheet material of the same material is provided. The first panel and the second panel are coupled on three sides on a periphery to form a weight-layer sleeve. The weight-layer sleeve is formed with the two panels coupled (e.g., sewn, welded, or otherwise attached) typically on three borders to make one pocket. Then the first panel and the second panel may be coupled on an interior with a plurality of longitudinal couplings to form a plurality of longitudinal columns, e.g., see the three longitudinal columns shown in FIG. 2 formed by seams 148. A first plurality of BBs 144 is disposed within the weight-layer sleeve in each of the plurality of columns and at a position proximate a sealed end. A first lateral coupling of the first panel and the second panel is formed so as to seal the first plurality of BBs 144 in each of the columns and thereby form a first row of sealed pockets containing BBs 144. A second plurality of BBs 144 is disposed within the weight-layer sleeve in each column and at a position proximate the first lateral coupling and a second lateral coupling of the first panel and the second panel is made to seal the second plurality of BBs 144 in each of the columns and thereby form a second row of sealed pockets containing BBs 144. Additional rows may be added in the same fashion until all the rows are done and the remainder of the periphery of the weighted-layer sleeve may be sealed.

In one embodiment, the pocket 140 of the weighted-segment layer 136 is formed with welded seams that have a seam width sized to allow the subsequent stitch to run down the weld seam without interfering with the pocket 140. In one embodiment, the seam width is 5 mm around the border and 10 mm cross the middle side to side and front to back. In another embodiment, a single weld pattern is done first that leaves at least one end open to the weight sleeve, a first row of BBs 144 is disposed therein, and then welding or sewing the next channel (lateral seam) in the weighted sleeve, and then filling the next row and repeating. In another embodiment, a die is used with a weld pattern, and the bottom layer of the weighted-segment layer 136 is put on the die and then the pockets filled with BBs where the weight of the BBs sags the fabric so that the BBs fall off the weld lines, and then adding a top sheet, and then compressing with a top die or flat plate or mimicked weld seam pattern, and the two sheets are welded together while encapsulating the BBs inside the pockets.

In one illustrative embodiment, the three columns (or longitudinal paths defined by the longitudinal edges 120, 124 and the two longitudinal seams 148) in FIG. 2 are welded and then one of the lateral ones 128 is formed. After that, the manufacturer puts in the first group of BBs 144. Then, the next lateral seam 128, e.g., weld, is placed and the process continues until the grid of BB-containing pockets 140 is completed. A rotating wheel may be used to weld as the fabric or material goes by the wheel. In another embodiment, a welding tool, which is a die in the shape of a desired pattern with areas to collect the BBs, is used, and the fabric or material of one side 244, of the weighted segment layer 136 is put on the die and the BBs 144 are added with the material flexing to hold the BBs 144. The BBs 144 gravitate towards the desired locations because of the die shape, and then the top layer (see side 240) of the weighted segment layer 136 is put on and a flat plate or a patterned member is brought down to form the weld. Another illustrative embodiment involves molding the BBs 144 into a layer, e.g., polyurethane rubber, that is included. In the sleeve 170.

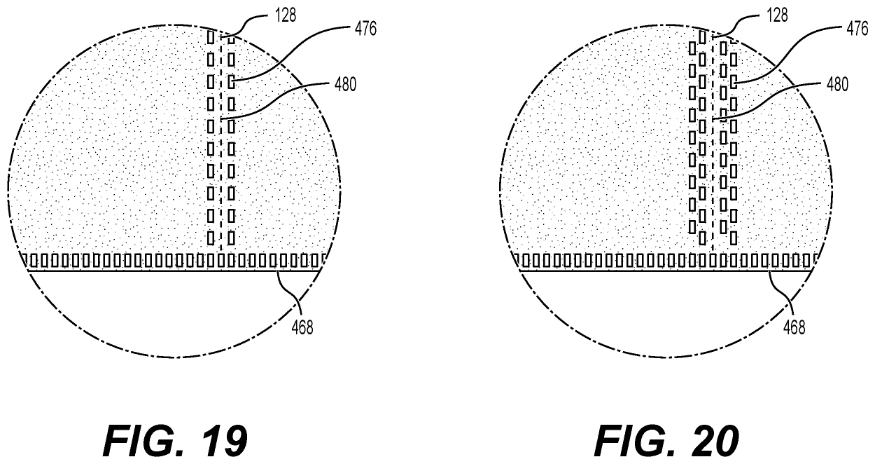

The welds or weld seams 128, 148 may form a pathway for any desired stitches (e.g., 480 in FIGS. 19 and 20) to be placed. In such embodiments, the sewing machine chases over the welding. If the weld is 10 mm wide, the stitch may be placed in the middle. In one illustrative embodiment, the stitching is only placed on the lateral seams 128. Of course, stitches may be placed on all the welds (128, 148, and peripheral edge) if desired. The stitching is typically not to secure the layers to make the pockets 140 but to secure the weighted segment layer 136 to another layer, such as the top layer, for stability.

In one illustrative embodiment, the weighted segment layer 136 is formed and then the top layer 132 is placed over the weighted layer 136 and the two layers 132, 136 are coupled by stitching. Then, the bottom layer 164 is coupled to the top layer 132 in due course. A foam, e.g., aero mesh foam, polyester shark tooth mesh, polypropylene foam, or any suitable insulator, may be disposed between the weighted segment layer 136 and the top layer 132. The foam layer 228 may be omitted in other embodiments. In one illustrative embodiment, the outer perimeter has a 5 mm weld. The internal lateral seams 148 have a 10 mm weld. The welds may be done with a particular pattern as suggested in connection with FIGS. 19 and 20. In any event in some embodiments, the welds are sized wide enough to allow stitching. The weighted layer 136 does not have to be coupled to anything but could be free within the sleeve 170. The weld pattern may be continuous across the length of welds 128, 148 or may be broken or patterned as shown in FIGS. 19, 20 wherein a plurality of proximal welded spots is separated by non-welded portion of the two fabric layers. The non-welded portion may help prevent propagation of any tear or rip in the weighted element.

The insulating layer 252 may be disposed below the weighted-segment layer 136. The insulating layer 252 has a first side 256 and a second side 260. The first side 256 of the insulating layer 252 is below the second side 244 of the weighted-segment layer 136, and the second side 260 of the insulating layer 252 is above the heating element 264. In one illustrative embodiment, as an aspect of the insulating layer 252, a reflective layer (e.g., mylar film or IR reflective surface with very low emissivity) may be included to reflect IR energy back toward the user.

The heating element 264, which may be a conductive layer 268, or otherwise resistive heating element, is below the weighted-segment layer 136 and in some embodiments is below the insulating layer 252. The conductive layer 268 may be a conductive rubber sheet. The conductive rubber layer 268 has a first side 272 and second side 276. The first side 272 of the conductive rubber layer 268 is below the second side 244 of the weighted-segment layer 136 and again in some embodiments is below the second side 260 of the insulating layer 252. In one illustrative embodiment, the conducting layer is 0.5 to 1.0 mm thick rubber with conductive particles.

In some embodiments, the heating element 264 may include multiple portions, e.g., a first heating element and a second heating element. The first heating element may comprise a radiating heating element that may be formed from any suitable material that is known to emit Far Infrared Waves (FIR heating) via black body radiation. Such material may be, but is not limited to, carbon fiber wiring wrapped in an undulating pattern. Other such radiating bodies may be similarly used to produce FIR heating. The second heating element of the heating element may be a conduction heating element made of a suitable material used to produce heat transfer through conduction. Such a heating element may be, but is not limited to, a copper or steel wire formed in an undulating pattern.

At least one thermistor may be included on or in the conductive rubber layer 268 and communicatively coupled to the printed circuit board 328 (FIG. 10) to assist in monitoring temperature; in this way a temperature almost at the user's skin is taken or calculated. “Skin” is used herein, but it is meant to include the user's garment or covering as well. One or more wires (or bus bar) may be coupled to the conductive rubber layer 268 and to one or more batteries in the battery housing 300, 308 (FIG. 6) to provide energy to the conductive rubber layer 268 through controller.

A bonding film 280 may be disposed between the second side 276 of the conductive rubber layer 268 and a first side 284 of the bottom layer 164 and in some embodiments may secure the conductive layer 268 to the insulating layer 252 to keep the conductive layer 268 from shifting around inside the sleeve 170. The bottom layer 164 has the first side 284 and a second side 288. The bottom layer 164 may be made of any suitable material and is formed from a PVC or TPU material. In one embodiment, the bottom layer 164 is thinner than the top layer since the bottom layer 164 needs to facilitate heat transfer to the user from the heating source and the top layer does not, and in fact should insulate the heat to drive the heat inward toward the body.

Referencing the right side of FIG. 6 along with FIGS. 6-8 and starting at the top for the orientation shown of FIG. 6, one may see components that are to one side (right side for orientation shown) of the final pleat 128. The right (for orientation shown) portion of FIG. 6 is a end portion that may include the battery cover 152, battery housing 300, electrical housing 356, battery 304, printed circuitry board, processor 332, and memory 336. The processor 332 and non-transitory member 336 may be referred to as a control unit. FIG. 7 shows a partially exploded view with certain components shown out front that would be in an interior location 298 when fully assembled. The battery cover 152, which may be a rubber molded battery cover, has a first side 292 and a second side 296. The second side 296 forms a concave portion that goes over a battery housing, e.g., first battery housing 300, which holds a first rechargeable battery 304.

While shown formed around the battery 304, in some embodiments space is left in the battery compartment that facilitates articulation of the portion proximate the second lateral end 116, and at the same time, the battery cover 152, which is typically molded, feels solid to the user. In some embodiments, including the one shown, a second rechargeable battery may be included in a second battery housing 308 (FIG. 7) on the other side and is analogous. The battery 304 may be a rechargeable lithium-ion battery, lithium polymer, acid batteries, cadmium batteries, metal hydride batteries, or other type of battery.

The battery housing 300 may be disposed on or proximate an insulating layer 252 or on the first side of the bottom layer 164. Similarly, the battery cover 152 also covers the electronics for controlling the heating pad 100 that reside at least in part within an electronics housing 312 and has a cooperating upper electronics panel 316.

Side walls 320 of the electronics housing 312 may have one or more openings 322 that may be filled by grommets, or slide panels 324. The openings 322 facilitate wire ingress and egress, e.g., wires from the batteries to the heating element, to the thermistors, etc. An interior portion 329 of the electronics housing 312 holds a printed circuit board (PCB) 328 (FIG. 10) having a processor 332 and a non-transitory memory 336; these components allow for functionality of the heating pad. The processor 332 and the memory 336 may be configured to carryout various tasks.

For example, the components referenced may allow the heating pad 100 to be turned on and ramp to a target heating level within 10-40 seconds and to monitor the resultant temperature to keep the temperature below a maximum. In one embodiment, the printed circuit board 328, at least one battery 304, and the heating element 264 are configured to ramp heat emitted by the heating element 264 to be within 80% of full heat within 10-20 seconds of activating the heating pad or alternatively between 60-90 seconds or 90-120 seconds or some other interval. In some embodiments, the printed circuit board 328, at least one battery 304, and the heating element 264 are configured to provide conductive and radiant heat in varying proportions during operation and during a startup phase.

In some embodiments, the various components forming the cross section of the heating pad 100 at the second longitudinal end 116 are coupled in a stack to give a solid feel to the user. For example, the molded battery cover 152 is fastened to the battery housing 300, which may be made from a hard plastic with apertures 348 for receiving pegs 344 from the battery cover 152. One may also use double-sided tape or some mild adhesive to couple the battery cover 152 to the battery housing 300. A hook-and-loop fastener may be used to secure the heating element 264 with the battery housing 300 on top of the second light foam layer 252. In some embodiments, not every layer is fastened, e.g., the hook-and-loop attachment may be omitted. Other fastening means like hooks, high friction components, magnets etc. may also be used to hold layers together and give a singular solid feel to the assembly.

In one embodiment the battery 304 is coupled to the battery housing 300 using a clamp on one end of the battery to the top rubber cover 304. The clamp may secure a portion of the battery housing to a portion of the layer or cover, for example a protruding edge or shelf that is molded into the top cover. The clamp may be done with fasteners, such as screws, or snap pegs or other means.

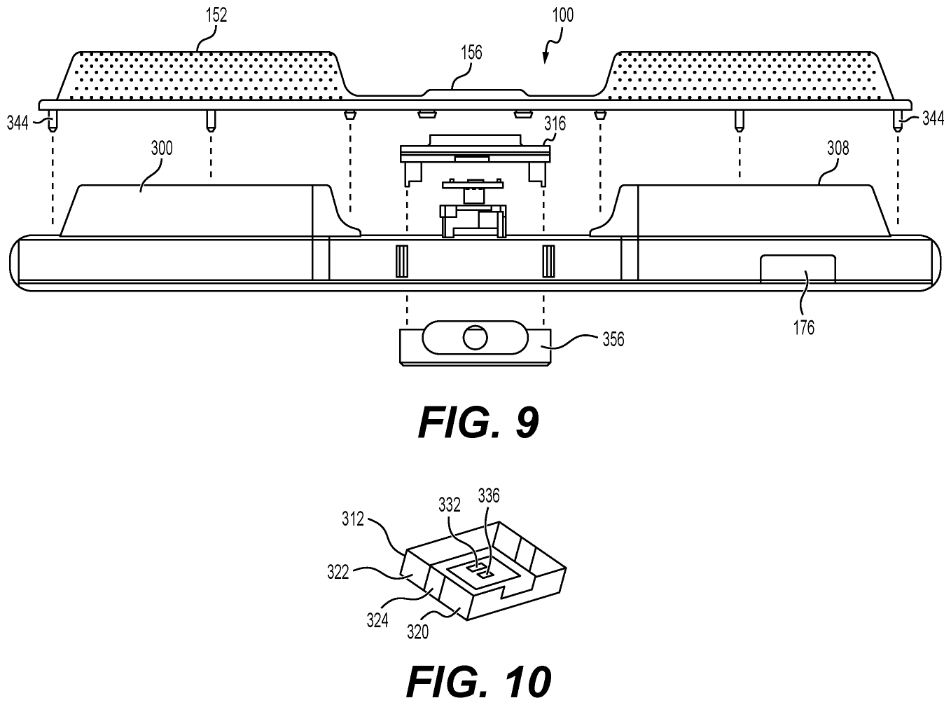

Referring now primarily to FIG. 9, one may see that the battery cover 152 has a plurality of snap-bosses or pegs 344 that go into coordinated apertures 348 (FIG. 7). The battery cover 152 may be coupled in other ways in other embodiments, such as two-sided tape, mild adhesive, flexible pockets that stretch around and grab bosses in the battery housings, screws or inserts molded into the battery cover for positively locking the battery cover to the battery housing etc.

Referring again to FIG. 7, a portion of the top fabric or bottom fabric may be pulled around on the second lateral end 116 and clamped between a front face 352 of the electrical housing and clamping bar 356. In some embodiments, a portion of the top layer and a portion of the bottom layer are clamped together by a clamp proximate the second longitudinal end. In some embodiments, a separate piece of fabric is used that is clamped. The clamped material can be a portion of the top, bottom, a separate piece, or a combination of any of those.

In some embodiments, temperature sensors may be placed on the heating element and a feedback loop used. In some embodiments, the temperature is measured at the heating element and not at the surface or close to the user's skin. There may be potential issues when sensors are used proximate the skin. When sensors are used proximate the skin the contact or lack of it in certain locations may be an issue.

For example, on a joint or uneven surface to which heating is applied, it can be difficult to get the temperature sensors to both contact the skin evenly with even pressure as it would on a flat or large curvature surface of the body (back/thigh/etc.). This is largely the situation because one cannot instrument the full surface of the heating pad with sensors for cost and complexity reasons. So, one chooses discreet points. Because of uneven contact pressure, the heat transfer at the point of measurement is different between the discrete sensors. A stronger contact pressure produces better heat transfer to the body which sinks more heat than air (air is an insulator) and causes the sensor temperature measurement to drop. If the sensor is placed on the bottom layer and not the heating element, then if the heating element layer separates from the bottom layer, the temperature at the sensor will drop because it is not connected to the heat source. In such an instance, the processor/memory might increase power, but this could overheat the skin of the user. In some embodiments, the processor and memory may include a negative feedback control loop algorithm that sees the temperature drop and increases power to the heater to make up for the drop.

If one sensor is poorly placed and dangling in the air, the body is not well connected and conduction is poor, this may make the temperature rise at that sensor; this rise in sensor temperature may cause the processor/memory to reduce power to the heating algorithm which reduces the heat that the pad is putting out. While this may lower the actual heat applied to the body below the intended setting, it at least promotes safety and avoids overheating a user's skin. In other words, put the sensors on the heating element and if one is away from the skin, that is okay and the power will still be reduced to keep that area from getting too hot. Contrarily, if sensors are applied to the inner layer and not coupled to the heating element, an unsafe condition may occur where the sensor separates form the heating element or contact pressure is reduced, the temperate at the sensor drops, power is increased to the entire heating element, and the user experiences higher heat levels than desired in the areas where there is good skin contact with the heating pad assembly.

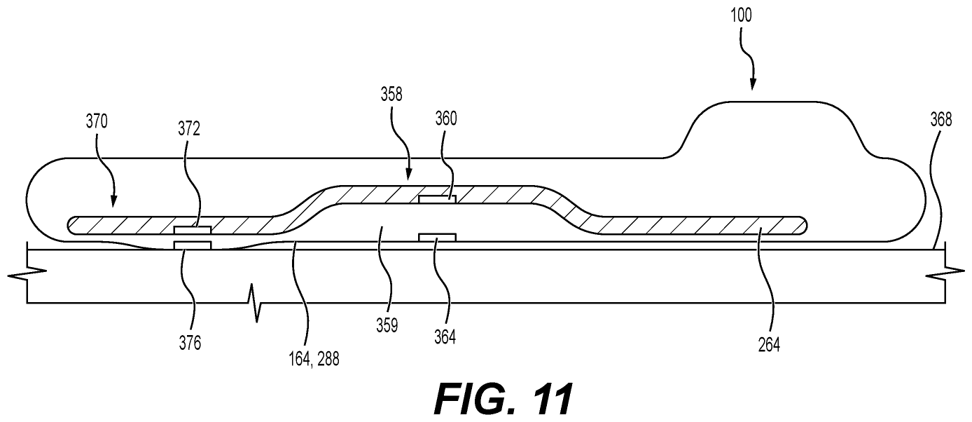

FIG. 11 shows a schematic cross-sectional view of the heating pad 100 with the heating element 264 shown. The heating element 264 has a non-contiguous surface, or contact, with the bottom layer 164 of the heating pad 100 and the gap is filled with air. It should be noted that it does not matter what medium is between the heating element 264 and the bottom layer 164, the general principles here hold true concerning the relative temperatures experienced.

In location 358, a first temperature sensor 360, e.g., thermistor, is connected at the surface of the heating element 264 itself and a second temperature sensor 364 is connected near the bottom layer 164 of the heating pad 100 (close to the skin 368 of the user). In location 370, a third temperature sensor 372 is still connected to the heating element 264 and a fourth temperature sensor 376 is still connected near the bottom layer 164 of the heating pad 100, however in this scenario there is good contact pressure holding the heating element tight against the skin surface 368. Location 358 represents a possible configuration of the heating pad 100 where the user casually lays it on a non-planar surface of their body and the rigidity of the heating pad 100 does not allow it to remain contiguous with the persons skin 368. In location 370, the two sensors 372, 376 read approximately the same value and there is little difference between the measured applied temperature. However, in location 358, the first sensor 360 will read much hotter than the second sensor 364 for a given heating element temperature because the air gap 359 is insulating the second sensor 360 from the heat source 264.

The reason this matters is that with a negative feedback executed by the processor and memory, or really any active control loop that is using temperature sensor data to regulate the power to the heating element 264, if the measured temperature is below target, the controller will increase power to increase the power to the heating element 264 to raise the temperature to the target value. If the measured temperature is above target, the controller will decrease the power to the heating element 264 to try and drop the temperature to the target value. So, when parts of the heating pad 100 are contiguous with the body surface or skin, in location 358, if the measured temperature is from the second sensor 364, the controller may falsely read the temperature is below the target temperature (because of the air gap 359), and command the controller to increase the power to the heating element 264. For the areas of the heating element 264 that are contiguous with the skin 368, this can lead to over temperature values. Therefore, in some embodiments, the temperature is measured at the heating element 264 itself (e.g., sensors 360, 372) and commanding off that value when running the control loop. In some embodiments, the heating pad 100 may also measure temperature at the skin 368 as well.

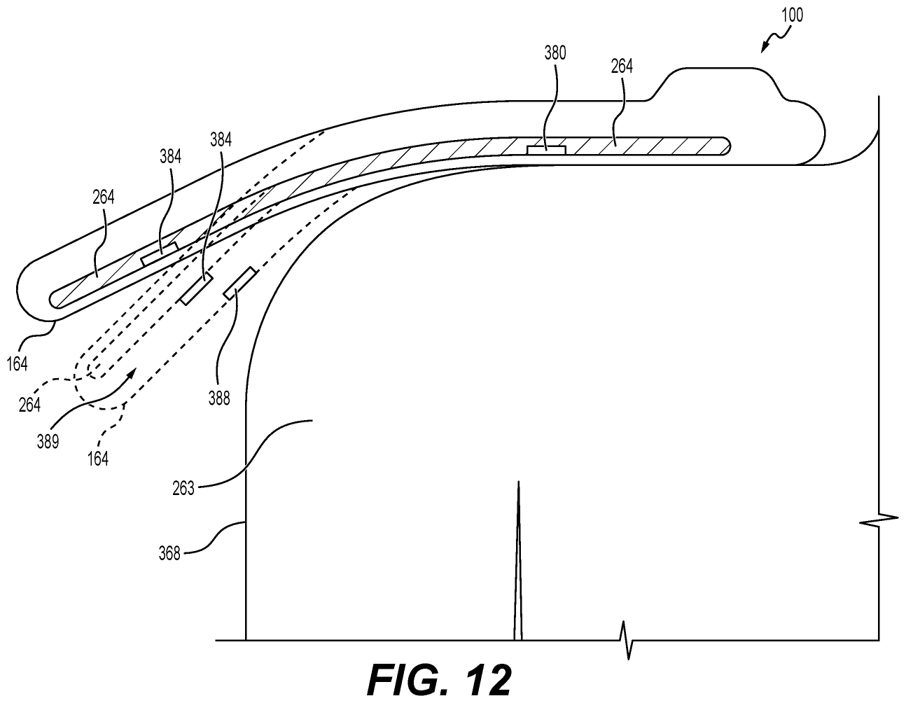

Referring now primarily to FIG. 12, an illustrative embodiment of a heating pad 100 is shown in cross section on a user's shoulder 263. The heating pad 100 is shown in two configurations or two illustrative embodiments. The solid line (Configuration 1) shows the heating element 264 contiguous with the bottom layer 164 of the heating pad 100. The dotted line (Configuration 2) shows the heating element 264 diverging from the bottom layer 164 of the heating pad 100. A fifth temperature sensor 380, sixth temperature sensor 384, and a seventh temperature sensor 388 are shown. The fifth temperature sensor 380, sixth temperature sensor 384, and seventh temperature sensors 388 represent Scenario A in Configuration 1, and Scenario B is represented with temperature sensors 380, 384 in Configuration 2.

Configuration 1 (solid lines) shows the heating pad 100 having good contact pressure with the skin 368 on the upper shoulder due to gravity, wrapping, or user holding a portion of the heating pad 100 down. The fifth sensor 380 reads similar values whether it is on the heating element 264 or near the bottom layer 164 of the heating pad 100. The sixth sensor 384 in the first position (Configuration 1) similarly remains near the bottom layer 164 and therefor may read similar values as if the sensor 384 were on the bottom layer 164. It is a different story for Configuration 2 (broken lines).

In Configuration 2, the heating element 264 shifts relative to the bottom layer 164 and diverges therefrom at the loose end of the heating pad 100 creating an air gap 389. In this scenario, a negative feedback control loop may take the average of temperature sensors 380, 384, and 388. The fifth sensor 380 is reading true contact temperature because of the high compression against the user, and the other sensors are reading different temperatures because they are not against the user.

In Configuration 1, the sixth sensor 384 in the first position is reading the heating element 264 temperature since the sensor 384 is connected to the heating element 264. Since there is no human body to sink heat away from the heating pad 100, the temperature of the sixth sensor 384 in the first position goes up quickly. This rise in temperature raises the average value, and through the control loop of the processor and memory decreases the power applied to the heating element 264. This will drop the power applied and drop temperature on fifth sensor 380 to promote safety.

In contrast, in Configuration 2, if the sixth sensor 384 is in the second position (broken lines; off the body at 62), the same scenario described above with Configuration 1 would hold true and power would decrease. However, if the seventh sensor 388 (one the bottom layer) were used, as sensor 388 has an insulating barrier away from the heating element 264 itself due to decreased contact pressure, the temperature at the seventh sensor 388 would drop, even below the measured temperature at the fifth sensor 380. In some embodiments, the temperatures may be averaged and a decrease in the seventh sensor 388 value will increase the power applied to the heating element 264 and the overall temperature will go up. That means the temperature at the fifth sensor 380 will increase to compensate for the decrease in the seventh sensor 388. An increase in power above a prescribed level could be undesirable.

For that reason, in an illustrative embodiment of a heating pad 100, the processor and memory are configured to decrease power when a lower temperature is observed compared to other sensors; that is indicated of not having good compression of the heating pad on the user. When the heating element 264 is not well placed with good contact pressure on the body, the power is reduced in order to promote safety. This concept applies to multiple temperature sensors as well as an individual sensor embodiments.

In one illustrative embodiment, the process may include one or more of the following:
Make sure the temperature sensor values are valid (not open/short circuit)
(optional): Measure a delta between temperature sensor values
(optional): If delta is greater than a threshold, cancel treatment.
Measure an average of temperature sensor values
If average is below a target, increase the power; If the average is above target, decrease the power
(Optional): Apply additional contact pressure to temperature sensor followed by an increase in power applied to the heating element by the controller
(Optional): Reduce contact pressure to the temperature sensor against the body followed by a decrease in power applied to the heating element by the controller.

The order of the steps may be varied and certain steps are optional.

Additional optional control steps that may be included:
Monitor the time from turn on to ensure the temperature values are increasing at an appropriate rate and shutdown if not heating correctly.
Monitor each temperature sensor to ensure the temperature sensor is increasing appropriately in temperature over time, shut down if it is not
Monitor each temperature sensor continuously for open/closed circuit action (set measurement thresholds on resistance), shut down if either condition sensed either before or during heating session.
Monitor each temperature sensor for over temperature, shut down if too high, i.e., beyond a threshold.

An alert step, such as a buzzer noise or LED signal, can be made to the user as an aspect of all of these.

In an illustrative embodiment, an averaging of multiple sensors all configured will behave the same way. If any sensor is off the surface, it will lower the overall power applied and drop the heat.

Note that the embodiments referenced here have the heat sensors on the heating element 264 itself. If the sensor is applied off the heating element 264, then if the section of heating pad 100 disengages from the body, the contact pressure reduces and the sensors does not read the heating element temperature accurately and its temperature will drop (it effectively displaces further away from the heating element). The drop in temperature will cause the power to rise to make up for the drop, causing the heating pad to apply more heat than desired, and this could cause a buildup in heat that when the heating pad is shifted back on the body could irritate the user's skin, or otherwise drain the batteries faster.

Said another way, when the temperature sensor 388 is on the bottom layer 164 and not on the heating element 264, there may be an issue with overheating. So, compare that to having sensor 384 on the heating element 264 itself which may have advantages. If the heating elements 384, 388 are coplanar, then the same temperature is experienced along the heating pad/user interface and everything reads accurately. If, however, there is an air gap 389 built in as shown between the bottom layer 164 and the heating element 264, the sensor 388 is going to drop when a gap is formed. So, normally the processor (e.g., 332 in FIG. 10 with programing from non-transitory memory 336) would say the temperatures dropping, so the system needs to increase power but if one does that, one might get the temperature too high. So, the processor/sensors detect that differential and instead reduces the power.

If the sensor 384 is adjacent the air gap 389 and away from the skin 368 of the user, the conductive heat loss to the skin goes down and there is air, which is an insulator, adjacent the sensor 384. Accordingly, the temperature at sensor 384 goes up. Air is insulating the sensor 384 from the heat sink, which is the user's body. So, the heating pad 100 gets hotter. In this embodiment, the processor 332 (with memory 336) will decrease the power which is safer when is realizes that a temperature is hotter than the average of the others or anyone of the others by a threshold amount, e.g., 2%, 5%, 10%, 20% or 30% or any other amount in the range 1-30%. Putting the temperature sensor on the heating element 264 is safer rather than on the bottom layer 164.

In one illustrative embodiment, the heating pad 100 includes a plurality of temperature sensors is coupled to the heating element and electrically coupled to the processor, and wherein the processor and a non-transitory memory are programmed to execute the following steps: check a temperature measurement from each of the plurality of temperature sensors; and lower power provided to the heating element if one of the plurality of temperature sensors has a temperature beyond a threshold difference (2-30%) between the other members of the plurality of temperature sensors or an average temperature from the plurality of temperature sensors.

In one illustrative embodiment, the heating pad 100 includes a plurality of temperature sensors, and the control unit (a processor and non-transitory memory) is programmed to execute the following steps:
monitor temperature reading from the plurality of temperature sensors; and
reduce power to the conductive layer if one of the plurality of temperature sensors has a temperature reading that is more than 5% hotter than a mean temperature of the plurality of temperature sensors or a temperature reading of any other of the plurality of temperature sensors.

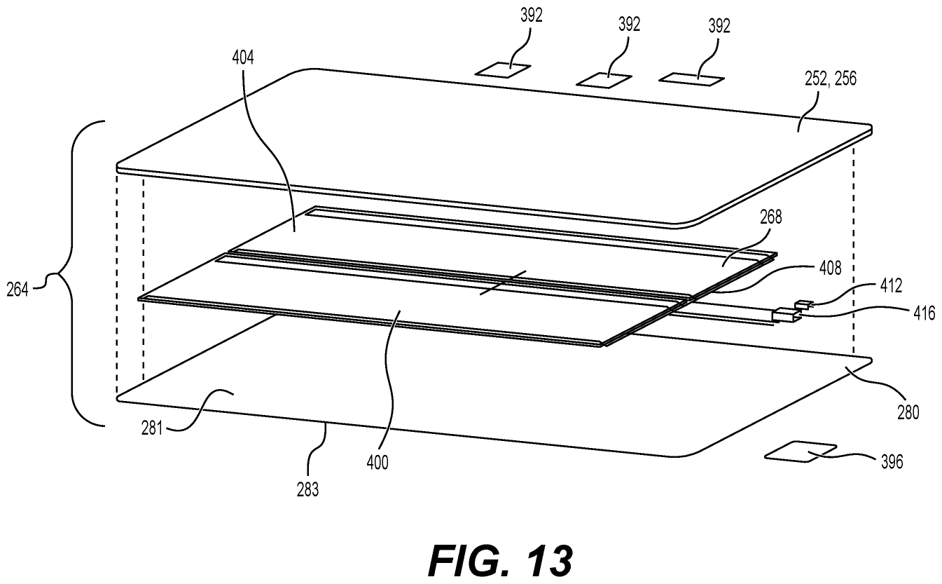

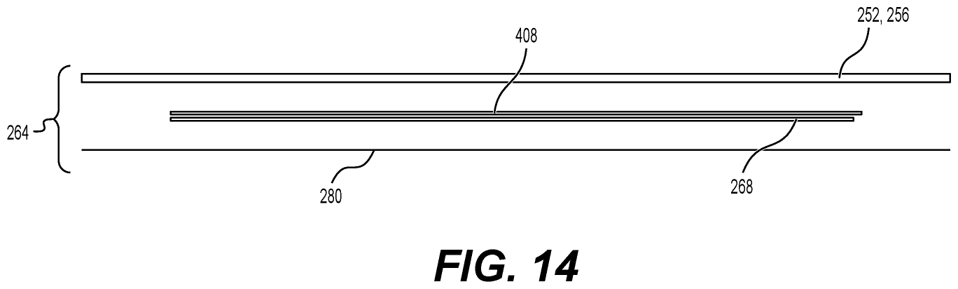

Referring now primarily to FIGS. 13-15, an illustrative embodiment of a heating element 264 is presented. The heating element 264 includes an insulating layer 252, and a bonding film 280 with a conductive layer 268 therebetween. The bonding layer 280 has a first side 281 and a second side 283. The heating on at 264 may include foam tape patches 392, such as neoprene tape patches. The heating element 264 may further include a label 396 coupled on the second side 283 of the bonding film 280.

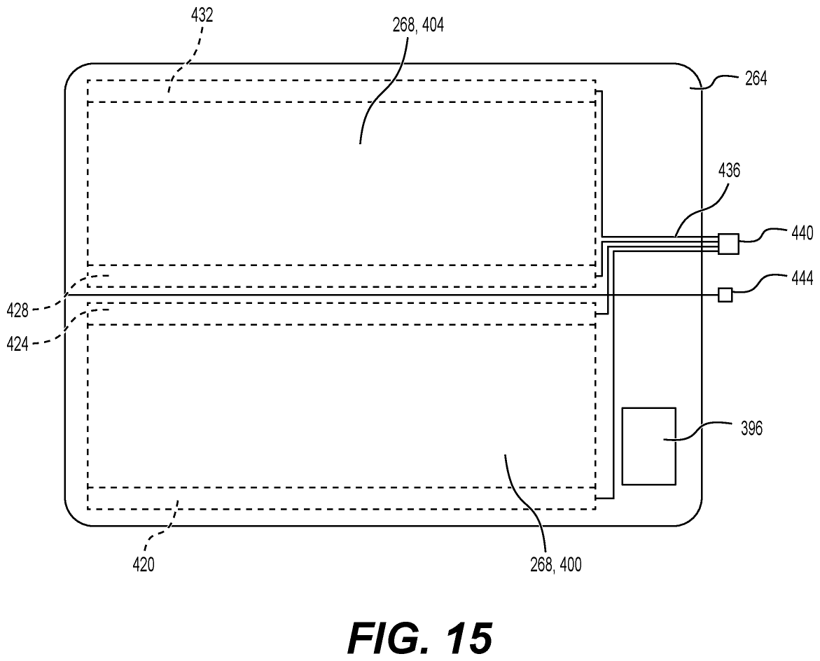

The conductive layer 268 may comprise a carbon-impregnated material that is able to carry a current across the surface. In the embodiment presented, the conductive layer 268 comprises a first conductive panel 400 and a second conductive panel 404. As described in connection with FIG. 15 below, the panels 400, 404 may be powered using bus bars on each side of the panels 404, 404. The heating element 264 includes a tinned copper braid wire 408 and a wiring harness 412. The tinned copper braid is coupled to the conductive sheet layer on opposite sides and with a positive potential on one side and a negative potential on the other such that current is driven across the conductive sheet in a substantially uniform manner. The bus bars may be sewn to the conductive material with one or more stitch seams or may be bonded or otherwise clamped to ensure good contact with the conductive material. The bus bars may run the length of the conductive material or only a portion of the length. A wiring harness may be coupled to the bus bars to provide the positive and negative potential via a second connection point which interfaces with the control electronics to carry the current used for heating. The wiring harness may allow for disconnection of the heating element or permanent connection with the control electronics. The heating element 264 also includes connectors and wires, e.g., 412 and 416.

Again, the heating element 264 is a conductive layer 268 or sheet. The conductive layer 268 is electrically and heat conductive material with a specific structure that generates heat when electrical current is passed therethrough. For example, in one illustrative embodiment, a 14-volt application is used with the following resistance characteristics for the given ambient temperatures.

TABLE 1

| Temp (F.) | Min Amp. | Max Amp. |
|---|---|---|
| 60 | 4.43 | 6 |
| 61 | 4.42 | 5.98 |
| 62 | 4.41 | 5.97 |
| 63 | 4.4 | 5.95 |
| 64 | 4.4 | 5.94 |
| 65 | 4.39 | 5.92 |
| 66 | 4.38 | 5.91 |
| 67 | 4.37 | 5.89 |
| 68 | 4.36 | 5.88 |
| 69 | 4.335 | 5.86 |
| 70 | 4.34 | 5.84 |
| 71 | 4.34 | 5.83 |
| 72 | 4.33 | 5.81 |
| 73 | 4.32 | 5.8 |
| 74 | 4.31 | 5.78 |
| 75 | 4.3 | 5.77 |
| 76 | 4.3 | 5.76 |
| 77 | 4.29 | 5.74 |
| 78 | 4.28 | 5.73 |
| 79 | 4.27 | 5.71 |
| 80 | 4.26 | 5.7 |
| 81 | 4.25 | 5.68 |
| 82 | 4.25 | 5.67 |
| 83 | 4.24 | 5.65 |
| 84 | 4.23 | 5.64 |
| 85 | 4.22 | 5.63 |
| 86 | 4.22 | 5.61 |
| 87 | 4.21 | 5.6 |
| 88 | 4.2 | 5.58 |
| 89 | 4.19 | 5.57 |
| 90 | 4.18 | 5.56 |

The resistance may be between 2.3 and 3.3 ohms for the illustrative conductive layer 268, which is carbon-impregnated rubber sheet to allow conduction across the entire sheet. In one illustrative embodiment, the conductive layer 268 comprises two panels 400, 404 that are connected in parallel, not in series. The panels 400, 404 do that to allow for a higher amp draw since the batteries have lower voltage and there is a resistance limit that exists with the fabric materials. The data in Table 1 is for the particular size given but it could be scaled for other applications. The power flux is the measure given in watts per square inch, and in this embodiment, the power flux is between 0.5 and 1.5 watts per square inch. In one embodiment, the power flux is one Watt per square inch or between 0.75 and 1.25 watts per square inch. In another embodiment a higher voltage may be used and heating panels may be wired in series. An advantage of parallel wiring may be that heating elements heat evenly at the same time whereas series wiring may cause one panel to heat before the other panel.

Referring now primarily to FIG. 15, which is a bottom view (from view of user when applied) of the heating element 264. The conductive layer 268 is shown in broken lines and one may see the first conductive panel 400 and the second conductive panel 404. A first bus bar 420 is one longitudinal side of the first conductive panel 400 and a second bus bar 424 to the other side. Likewise, the second conductive panel 404 has a third bus bar 428 and a fourth bus bar 432. Conductive wires 436 may couples the bus bars to a wire harness 440. A number of connectors and wires are shown, e.g., 440, 444.

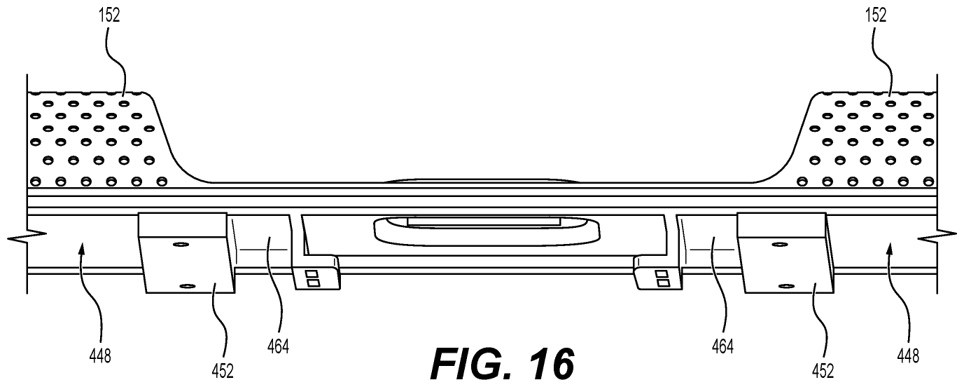

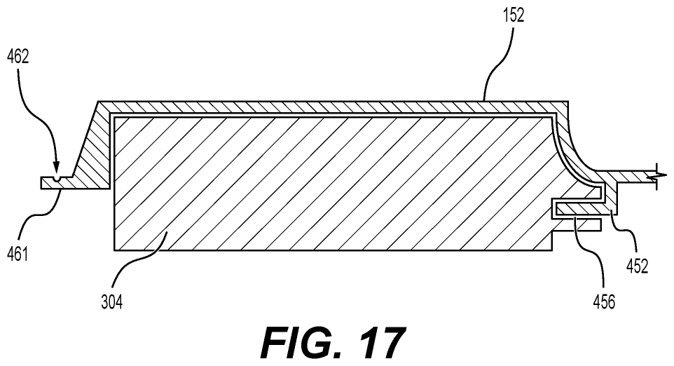

Referring now primarily to FIGS. 2, 16, and 17, the attachment of a battery 304 to the battery cover 152 is described in further detail. As shown clearly in FIG. 16, the battery cover 152 is formed with a battery cavity 448 for receiving at least a portion of a battery 304. The battery cover 152 may be formed with a ledge 452. The ledge 452 is sized and configured to mate or be sandwiched in a receiving slot 456 (FIG. 17).

Concerning the attachment of the first battery or second battery to the battery cover 152, there is a clamp, which is formed as a ledge 452 (FIG. 16) that goes into a slot 456 (FIG. 16). On the battery cover 152 there is a cavity448 to receive portion of the battery 304, but just below that there is a ledge 452 that is made to go into a designated shelf area or a slot 456. The ledge 452 receives a protrusion portion that has the slot 456 on the protrusion.

As another aspect of the battery cover 152, note in FIG. 16 the reduced thickness portions 464 in a couple places, or reduced material portions. The reduced thickness portions 464 are aligned with the internal longitudinal stitching 148 (FIG. 2) and help facilitate the battery cover 152 flexing at those locations as the heating pad 100 is wrapped or positioned around or next to a portion of a user.

FIG. 17 shows a flange portion 461. The flange portion 461 has a stitch channel 462, or sewing groove, along which the flange portion 461 may be sewed to a layer of material.

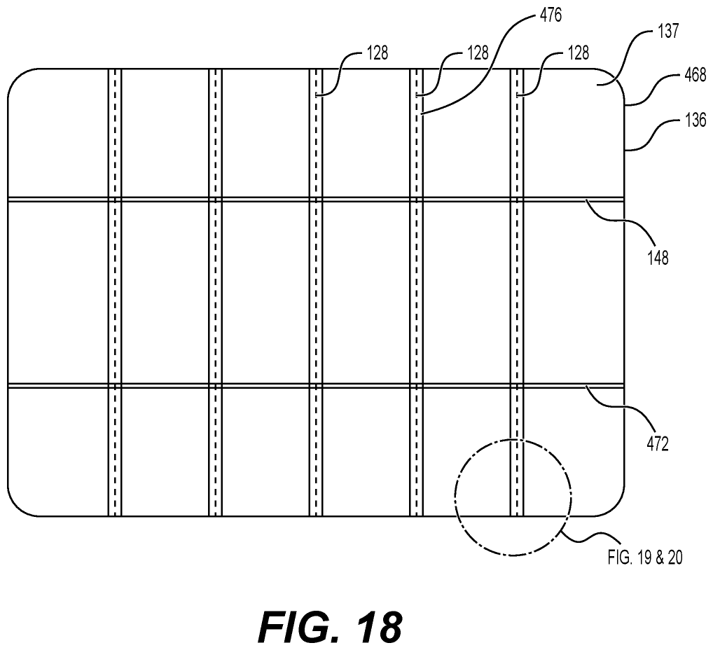

Referring now primarily to FIGS. 18-20, an illustrative embodiment of the weighted segment layer 136 is described. The weighted segment layer a top layer 137 and bottom layer (opposite the top layer 137) that are coupled on a peripheral edge 468. The longitudinal seam 148 may be formed with sonic welds or other welds 472. The seams (or hinges or lateral seams) 128 may be formed by sonic welds or other welds 476.

With reference to FIGS. 19 and 20, the welds 472, 476, and welds on the perimeter 468 may take various forms and form different patterns and sizes. For example, the figures show a train track style weld pattern on the perimeter 468. FIG. 19 shows a train track weld patter for welds 476 on the lateral seams 128. FIG. 20 shows an alternating displaced patter 476 that may help deter rips from spreading. The various seems may be formed by welds along, stitches, or stitches and welds. In FIGS. 19 and 20, one may see that the lateral seams 128 include stitches. In each case, the weld pattern used has a distance between adjacent welds (if not solid) that are less than the width of the BBs or plurality of weights in the formed pockets; for example, if the BBs are 3 mm in diameter, the distance between welds is less than 3 mm so as to contain the BBs.

The heating pad 100 with its constituent layers is flexible enough to bend or articulate around body parts of a user. The seams 148, 128, and reduced material areas 464 of the battery cover 152 may facilitate the same.

In one illustrative embodiment, the printed circuit board, at least one battery, and the heating element are configured to provide conductive and radiant heat in varying proportions during a startup phase.

In one illustrative embodiment, the heating pad explicitly uses far infrared (FIR). Far infrared radiation is often defined as a subdivision of the electromagnetic spectrum in the range of 3-100 micrometers. FIR penetrates much deeper—in some instances as much as 8 to 10 times deeper than mere conduction heat. FIR is a better heating modality for helping with recovery—better than conducting, surface-based heat transfer.

With FIR alone, the user may not feel heat and in a psychological sense may believe that nothing is happening. FIR, in general, runs at a much lower temperature because it is driven by radiation, which works by heating from the inside out, heating deeper. Conversely, conductive heat is superficial in nature, which stimulates the heat thermoreceptors found in the skin. This broadcasts the perception of heat to the brain for a different user experience or perception. The heating pad 100 addresses the heat perception issue by providing a sensation of heat through conductive heat. In one aspect, the present disclosure addresses this issue by using both conduction and radiant heat. In some embodiments, this is done with a single, dual-function heating element and in another by having two separate heating elements: one conduction and radiant.

In one illustrative embodiment, a material, such as a conductive elastomer or conductive rubber sheet, may be used as the conductive layer 268 to provide the heat. The conductive sheet or layer may be a rubber with a metal or other conductive particles added such as silver, nickel, silvered glass, silvered aluminum, or graphite. In other embodiments, the conductive sheet may comprise an oriented wire in a solid silicone, metalized filled silicones, wire screen embedded into silicone, conductive fabric, carbon fiber wool, or other material.

In this regard, a carbon fiber wire is an efficient emitter of FIR radiation but not a great conductor, therefore multiple circuits of wire may be required as an aspect of the heating element 264. Metal wire may be a good conductor of electricity and superficial heating, but may be a poorer generator of FIR radiation. Whereas energizing a wire is straightforward, conductive sheets or layers may generally have electricity passed through them from one side to the other via conductive bus bars coupled at opposite ends of the sheet. A positive voltage is applied to one bus bar and a negative voltage to the other, and current is then driven across the conductive sheet via this voltage differential to produce heat. A conductive sheet may offer advantages in terms of more even complete heating than a wire because current is passing through the entire surface area vs an undulating pattern that only covers a fraction of the surface area. A wire type of conductor may have an advantage where multi-degree articulation is required or where bus bars may not be easily applied parallel to one another which can cause un-even heating across a conductive sheet. The at least one heating element is meant to include either approach.

In the case wiring as an aspect of the heating element, is used, a conductive heat transfer material wire (e.g., copper) may run in parallel with a principally FIR radiating material (e.g., carbon fiber) and the conductive wire energized in the beginning stage of the session, for example for 1-2 min, to apply a noticeable and perceivable heat to the surface of the body, and then turned off while the principally FIR generating material is energized. The energization of the two materials may additionally overlap so there is a smooth transition between principally conductive heat transfer and principally FIR radiation heat transfer.

With a conductive sheet or layer 268, the heat may be initially ramped with relatively high power applied such that the material produces a conductive heat that allows the user to superficially experience heat—heat at a level that might not be sustainable for a long treatment. After that, the power applied is lowered such that the material may provide heat through FIR to a greater extent. It should be understood that in the power variations, both conductive and radiant heat are developed but the proportions can be impacted by the power regiment. The initial “heat ramp” allows the user to experience an initial heat sensation while FIR is used for deeper treatment. In one illustrative embodiment, to cause the conductive layer to generate the conductive heat, the heating pad 100 may provide a significant amount of power to the conductive layer, e.g., 30, 40, 50-100 watts or another amount for about 1-2 minutes, and then it is ramped down. Other power settings and durations may be used in other applications as one skilled in the art will perceive from this disclosure. In another illustrative embodiment, this ramping-decreasing pattern is repeated periodically.

In one illustrative embodiment, the processor and non-transitory memory include software or programming that provides power to the heating element with a desired temperature profile. For example, an illustrative, qualitative temperature profile includes a quick ramping portion that leads to a treatment temperature before energy is terminated or reduced at an energy adjustment point allowing for a tapering of the temperature at the right segment. It should be understood that steeper or slower ramping portions may be used. In some embodiments, the temperature may be cycled to have a tooth appearance or oscillation at the treatment temperature as shown. The controlled temperature profiles may have the advantage of cutting down on the time that the unit is worn and may enhance the user's perception of the product as it heats quickly. Moreover, an advantage may include a therapeutic benefit of quickly ramping the temperature.

In another illustrative embodiment, the temperature may be programmed to ramp overshoot the treatment temperature and ramp down to the treatment temperature or target temperature over a period of time. This ramping of the heat may have the perceptual advantage to the user that the treatment is working without risking burning the user due to prolonged heat at an elevated temperature.

There may many advantages to the heating pads presented herein. For example, the heating pads herein may be easy to wipe clean. As other examples, the heating pads may be portable, flexible, and safer than previous designs.

As should be clear, there are many illustrative embodiments. Other examples follow.

Example 1. A heating pad for application on a portion of a user's body, the heating pad comprising:
a top layer having a first side and a second side;
a weighted-segment layer having a plurality of pockets and having a first side and a second side, wherein the first side of the weighted-segment layer is below the second side of the top layer;
a heating element comprising a conductive rubber layer having a first side and second side, wherein the first side of the conductive rubber layer is below the second side of the weighted-segment layer;
at least one thermistor associated with the conductive rubber layer;
a bottom layer having a first side and a second side, and wherein the first side of the bottom layer is below the second side of the conductive rubber layer.
a plurality of lateral seams formed at least by coupling a portion of the top layer and a portion of the weighted-segment layer;
a battery housing;
an electronics housing;
a battery cover;
a printed circuit board;
at least one battery electrically coupled to the printed circuit board and to the heating element;
a coupled peripheral edge formed by coupling the top layer and bottom layer at peripheral ends whereby a sleeve is formed that contains at least the weighted-segment layer and heating element.

Example 2. The heating pad of Example 1, wherein a portion of the cover that is at a different thickness than another portion of the cover, the thicker portion housing the batteries and electronics, and having a fabric pattern and potentially other pieces of fabric configured to provide that extra thickness while allowing articulation and bending of the assembly.

Example 3. The heating pad of Example 1, further comprising:
a first compressible foam layer having a first side and a second side, wherein the first side of the first compressible foam layer is below the second side of the top layer and the second side of the first compressible foam layer is above the first side of the weighted-segment layer.

Example 4. The heating pad of Example 3, further comprising:
an insulating layer having a first side and a second side, wherein the first side of the insulating layer is below the second side of the weighted-segment layer and the second side of the insulating layer is above the heating element.

Example 5. The heating pad of Example 4, further comprising a bonding film disposed between the second side of the insulating layer and the bottom layer.

Example 6. The heating pad of Example 1, wherein the battery cover comprises a molded rubber and covers at least one batter and a printed circuit board.

Example 7. The heating pad of Example 1, wherein the weighted-segment layer comprises a plurality of pockets filled with BBs or small weights.

Example 8. The heating pad of Example 1, further comprising a zipper formed on the coupled peripheral edge.

Example 9. The heating pad of Example 8, wherein the zipper is a hidden zipper.

Example 10. The heating pad of Example 1, wherein the printed circuit board, at least one battery, and the heating element are configured to ramp heat emitted by the heating element to be within 80% of full heat within 10-20 seconds of activating the heating pad.

Example. 10.1. The heating pad of Example 1, wherein the printed circuit board, at least one battery, and the heating element are configured to ramp heat emitted by the heating element to be within 80% of full heat within 60-90 seconds of activating the heating pad.

Example 10.2. The heating pad of Example 1, wherein the printed circuit board, at least one battery, and the heating element are configured to ramp heat emitted by the heating element to be within 80% of full heat within 90-120 seconds of activating the heating pad.

Example 11. The heating pad of Example 1, wherein the printed circuit board, at least one battery, and the heating element are configured to provide conductive and radiant heat in varying proportions during a startup phase.

Example 12. The heating pad of Example 1,
wherein the heating pad has a first longitudinal end and a second longitudinal end,
wherein the battery housing, the electronics housing, the battery cover, and the printed circuit board are positioned proximate the second longitudinal end; and
wherein the battery cover and battery housing are coupled to each other.

Example 13. The heating pad of Example 12, wherein a portion of the top layer and a portion of the bottom layer are clamped together by a clamp proximate the second longitudinal end.

Example 14. The heating pad of Example 1, wherein a plurality of temperature sensors is coupled to the heating element and electrically coupled to the processor.

Example 15. A method of manufacturing a weighted segmented layer comprising:
providing a first panel of sheet material and a second panel of sheet material;
coupling the first panel and the second panel on three sides on a periphery to form a weight-layer sleeve;
coupling the first panel and the second panel with a plurality of longitudinal couplings to form a plurality of longitudinal columns;
disposing a first plurality of BBs within the weight-layer sleeve in each of the plurality of columns and at a position proximate a sealed end;
forming a first lateral coupling of the first panel and the second panel so as to seal the first plurality of BBs in each of the columns and thereby form a first row of sealed pockets containing BBs;
disposing a second plurality of BBs within the weight-layer sleeve in each column and at a position proximate the first lateral coupling; and
forming a second lateral coupling of the first panel and the second panel so as to seal the second plurality of BBs in each of the columns and thereby form a second row of sealed pockets containing BBs.

“Coupled” as used herein includes indirectly coupled, e.g., battery housing coupled to a layer via a third component.

Although the present invention and its advantages have been disclosed in the context of certain illustrative, non-limiting embodiments, it should be understood that various changes, substitutions, permutations, and alterations can be made without departing from the scope of the invention as defined by the claims. It will be appreciated that any feature that is described in a connection to any one embodiment may also be applicable to any other embodiment.

What is claimed:

1. A heating pad for application on a portion of a user's body, the heating pad comprising:
a top layer having a first side and a second side, wherein top means furthest from the user's body when in an applied potion;
a weighted-segment layer having a plurality of pockets and having a first side and a second side, wherein the first side of the weighted-segment layer is below the second side of the top layer;
a heating element comprising a conductive layer having a first side and second side, wherein the first side of the conductive layer is below the second side of the weighted-segment layer, and wherein the conductive layer creates heat when a current moves across the conductive layer;
at least one thermistor associated with the conductive layer;
a bottom layer having a first side and a second side, and wherein the first side of the bottom layer is below the second side of the conductive layer; and
an end portion coupled to the top layer or bottom layer, wherein the end portion comprises:
battery housing coupled at least to the top layer or bottom layer or a battery cover,
the electronics housing coupled at least to the top layer or bottom layer or the battery cover,
the battery cover coupled at least to the top layer or bottom layer or the battery housing,
a printed circuit board associated with the electronics housing, and
at least one battery electrically coupled to the printed circuit board and to the heating element.

2. The heating pad of claim 1, wherein the heating pad further comprises a plurality of seams formed at least by coupling a portion of the top layer and a portion of the weighted-segment layer.

3. The heating pad of claim 1, wherein the heating element is configured to have a power flux between 0.5 and 1.5 watts per square inch.

4. The heating pad of claim 1, wherein a portion of the battery cover is thinner than other portions of the battery cover to facilitate articulation of the battery cover.

5. The heating pad of claim 1, wherein the battery cover is formed with a battery cavity and a ledge sized and configured to mate with a slot formed on the at least one battery.

6. The heating pad of claim 1, further comprising a coupled peripheral edge formed by coupling the top layer and bottom layer at peripheral ends whereby a sleeve is formed that contains at least the weighted-segment layer and the heating element.

7. The heating pad of claim 1, further comprising: a first compressible foam layer having a first side and a second side, wherein the first side of the first compressible foam layer is below the second side of the top layer, and wherein the second side of the first compressible foam layer is above the first side of the weighted-segment layer.

8. The heating pad of claim 7, further comprising: an insulating layer having a first side and a second side, wherein the first side of the insulating layer is below the second side of the weighted-segment layer, and wherein the second side of the insulating layer is above the heating element.

9. The heating pad of claim 8, further comprising a bonding film disposed between the second side of the insulating layer and the bottom layer.

10. The heating pad of claim 1, wherein the battery cover comprises a molded rubber and covers at the least one battery and a printed circuit board.

11. The heating pad of claim 1, wherein the weighted-segment layer comprises a plurality of pockets filled with a plurality of weights under 0.5 grams/each.

12. The heating pad of claim 1, further comprising a hidden zipper formed on the coupled peripheral edge.

13. The heating pad of claim 1, wherein the printed circuit board, at least one battery, and the heating element are configured to ramp heat emitted by the heating element to be within 80% of full heat within 10-20 seconds of activating the heating pad.

14. The heating pad of claim 1, wherein the printed circuit board, at least one battery, and the heating element are configured to ramp heat emitted by the heating element to be within 80% of full heat within 60-90 seconds of activating the heating pad.

15. The heating pad of claim 1, wherein the printed circuit board, at least one battery, and the heating element are configured to provide conductive and radiant heat in varying proportions during a startup phase.

16. The heating pad of claim 1, wherein the plurality of pockets formed on the weighted segmented layer is consistent with a ratio of one pocket per 5 to 10 square inches.

17. The heating pad of claim 1,
wherein the heating pad further comprises a plurality of seams formed at least by coupling a portion of the top layer and a portion of the weighted-segment layer using welds having at least in some places a staggered weld pattern;
wherein the heating element is configured to have a power flux between 0.5 and 1.5 watts per square inch;
wherein a portion of the battery cover is thinner than other portions of the battery cover to facilitate articulation of the battery cover;
further comprising a coupled peripheral edge formed by coupling the top layer and bottom layer at peripheral ends whereby a sleeve is formed that contains at least the weighted-segment layer and the heating element;
further comprising a first compressible foam layer having a first side and a second side, wherein the first side of the first compressible foam layer is below the second side of the top layer, and wherein the second side of the first compressible foam layer is above the first side of the weighted-segment layer;
further comprising an insulating layer having a first side and a second side, wherein the first side of the insulating layer is below the second side of the weighted-segment layer, and wherein the second side of the insulating layer is above the heating element;
further comprising a bonding film disposed between the second side of the insulating layer and the bottom layer;
wherein the weighted-segment layer comprises a plurality of pockets filled with a plurality of weights under 0.5 grams/each;
further comprising a hidden zipper formed on the coupled peripheral edge; and
wherein the plurality of pockets formed on the weighted segmented layer is consistent with a ratio of one pocket per 5 to 10 square inches.

18. The heating pad of claim 1, wherein a plurality of temperature sensors is coupled to the heating element and electrically coupled to the processor, and wherein the processor and a non-transitory memory are programmed to execute the following steps:
check a temperature measurement from each of the plurality of temperature sensors; and
lower power provided to the heating element if one of the plurality of temperature sensors has a temperature beyond a threshold.

19. A heating pad comprising:
a sleeve formed with a top layer and a bottom layer and having an interior, wherein the bottom layer is against a user when in a deployed position;
a weighted segment layer disposed within the interior of the sleeve, wherein the weighted segment layer comprises a plurality of pockets each having a plurality of weights therein;
a conductive layer disposed within the interior of the sleeve closer to the user than the weighted segment layer when in the deployed position;
wherein the conductive layer is configured to have a power flux between 0.5 and 1.5 watts per square inch;
a battery and control unit electrically coupled to the conductive layer for selectively providing power to the conductive layer;
wherein the sleeve, weighted segment layer, and conductive layer are flexible enough to articulate about portions of the user's body; and
at least one temperature sensor coupled to the conductive layer and electrically coupled to the control unit.

20. The heating pad of claim 19, wherein the at least one temperature sensor comprises a plurality of temperature sensors, and wherein the control unit comprises a processor and non-transitory memory and wherein the control unit is programmed to execute the following steps:
monitor temperature reading from the plurality of temperature sensors; and
reduce power to the conductive layer if one of the plurality of temperature sensors has a temperature reading that is more than 5% hotter than a mean temperature of the plurality of temperature sensors or a temperature reading of any other of the plurality of temperature sensors.

21. The heating pad of claim 19, wherein the conductive layer is a carbon-impregnated conductive sheet configured to have a power flux between 0.5 and 1.5 watts per square inch.
